(19) United States
(12) Patent Application Publication
(10) Pub. No.: US 2023/0403824 A1
(43) Pub. Date: Dec. 14, 2023

(54) COOLING SYSTEM, CONTROL METHOD AND DATA CENTER COMPUTER ROOM

(71) Applicant: Hebei Qinhuai Data Co., Limited., Zhangjiakou City (CN)

(72) Inventors: Binghua ZHANG, Zhangjiakou City (CN); Mingjiang LI, Zhangjiakou City (CN); Zhenghua WANG, Zhangjiakou City (CN); Tao LU, Zhangjiakou City (CN)

(21) Appl. No.: 18/208,904

(22) Filed: Jun. 13, 2023

(30) Foreign Application Priority Data
Jun. 14, 2022 (CN) 202210670538.8

(51) Int. Cl. H05K 7/20

(52) U.S. Cl. CPC H05K 7/20354; H05K 7/20327; H05K 7/20827

(57) ABSTRACT

The present disclosure discloses a cooling system, a control method and a data center computer room. The cooling system includes an evaporative cooling module, an oilless centrifugal compressor, a condensing module, a circulating pump module, and a throttling module. A first output end of the evaporative cooling module is connected to an input end of the oilless centrifugal compressor, an output end of the oilless centrifugal compressor is connected to an input end of the condensing module; an output end of the condensing module is connected to an input end of the circulating pump module, an output end of the circulating pump module is connected to an input end of the throttling module; and an output end of the throttling module is connected to an input end of the evaporative cooling module, and a second output end of the evaporative cooling module leads to an air supply channel.

### CROSS-REFERENCE TO RELATED APPLICATION

This application claims priority to Chinese Patent Application No. 202210670538.8, titled “COOLING SYSTEM, CONTROL METHOD AND DATA CENTER COMPUTER ROOM” and filed to the China National Intellectual Property Administration on Jun. 14, 2022, the entire contents of which are incorporated herein by reference.

### TECHNICAL FIELD

The present disclosure relates to the field of air conditioning technology, and more particularly, to a cooling system, a control method and a data center computer room.

### BACKGROUND

In information era, a scale of data centers is getting larger and larger, and an integration level thereof is getting higher and higher. To ensure stable operation of electronic devices in a data center computer room, it is required to adjust a temperature of the computer room by means of air conditioners, to maintain the temperature of the computer room within a reasonable range.

The traditional computer room adopts mechanical refrigeration, and an indirect evaporative cooling air conditioning unit is a common mechanical refrigeration air conditioning unit. The refrigeration process consumes a lot of energy and uses a lot of cooling water.

However, countries and regions have issued new policies to limit Power Usage Effectiveness (PUE) values of the data centers. Obviously, the above-mentioned indirect evaporative cooling air conditioning unit has higher energy consumption and cannot reduce the PUE values of the computer room.

### SUMMARY

The present disclosure provides a cooling system, a control method and a data center computer room. A temperature of the computer room is adjusted by utilizing an oilless centrifugal compressor to reduce energy consumption of air conditioners in the computer room, thereby realizing the objective of reducing a Power Usage Effectiveness (PUE) value of the computer room.

In a first aspect, an embodiment of the present disclosure provides a cooling system, which includes:

an evaporative cooling module, an oilless centrifugal compressor, a condensing module, a circulating pump module and a throttling module, where a first output end of the evaporative cooling module is connected to an input end of the oilless centrifugal compressor, an output end of the oilless centrifugal compressor is connected to an input end of the condensing module; an output end of the condensing module is connected to an input end of the circulating pump module, an output end of the circulating pump module is connected to an input end of the throttling module; an output end of the throttling module is connected to an input end of the evaporative cooling module, and a second output end of the evaporative cooling module leads to an air supply channel.

The evaporative cooling module is configured to, when an outdoor temperature is higher than or equal to a preset temperature, exchange heat with indoor hot air and a throttled refrigerant to obtain cold air and refrigerant gas, transfer the refrigerant gas to the oilless centrifugal compressor through the first output end, and transfer the cold air to an electronic device through the air supply channel by means of the second output end.

The oilless centrifugal compressor is configured to compress the refrigerant gas to obtain a compressed gas refrigerant.

The condensing module is configured to condense the compressed gas refrigerant into a liquid refrigerant.

The circulating pump module is configured to adjust a pressure of the liquid refrigerant.

The throttling module is configured to throttle the pressure-adjusted liquid refrigerant to obtain the throttled refrigerant.

In a second aspect, an embodiment of the present disclosure provides a data center computer room, which includes a computer room internally provided with the cooling system as described in the first aspect or various implementations of the first aspect.

In a third aspect, an embodiment of the present disclosure provides a control method for a cooling system. The control method is applied to an evaporative cooling module, an oilless centrifugal compressor, a condensing module, a circulating pump module, and a throttling module. A first output end of the evaporative cooling module is connected to an input end of the oilless centrifugal compressor, an output end of the oilless centrifugal compressor is connected to an input end of the condensing module; an output end of the condensing module is connected to an input end of the circulating pump module, an output end of the circulating pump module is connected to an input end of the throttling module; and an output end of the throttling module is connected to an input end of the evaporative cooling module, and a second output end of the evaporative cooling module leads to an air supply channel. The control method includes:
when an outdoor temperature is higher than or equal to a preset temperature, exchanging heat with indoor hot air and a throttled refrigerant by means of the evaporative cooling module to obtain cold air and refrigerant gas;
compressing the refrigerant gas by means of the oilless centrifugal compressor to obtain a compressed gas refrigerant;
condensing the compressed gas refrigerant into a liquid refrigerant by means of the condensing module;
adjusting a pressure of the liquid refrigerant by means of the circulating pump module; and
throttling the pressure-adjusted liquid refrigerant by means of the throttling module to obtain the throttled refrigerant.

The embodiments of the present disclosure provide a cooling system, a control method and a data center computer room. The cooling system includes an evaporative cooling module, an oilless centrifugal compressor, a condensing module, a circulating pump module, and a throttling module. A first output end of the evaporative cooling module is connected to an input end of the oilless centrifugal compressor, an output end of the oilless centrifugal compressor is connected to an input end of the condensing module; an output end of the condensing module is connected to an input end of the circulating pump module, an output end of the circulating pump module is connected to an input end of the throttling module; and an output end of the throttling module is connected to an input end of the evaporative cooling module, and a second output end of the evaporative cooling module leads to an air supply channel. In the process of adjusting the temperature of the computer room, the cooling system exchanges heat with the indoor hot air and the throttled refrigerant by means of the evaporative cooling module to obtain the cold air and the refrigerant gas, transfers the refrigerant gas to the oilless centrifugal compressor through the first output end, and transfers the cold air to an electronic device through the air supply channel by means of the second output end. The refrigerant gas is compressed by means of oilless centrifugal compressor to obtain the compressed gas refrigerant, which is condensed into the liquid refrigerant by the condensing module. The pressure of the liquid refrigerant is adjusted by the circulating pump module, and then the pressure-adjusted liquid refrigerant is throttled by the throttling module to obtain the throttled refrigerant, which enters the evaporative cooling module. By adopting this solution, the temperature of the computer room is adjusted by using the oilless centrifugal compressor, and energy consumption of air conditioners in the computer room is reduced, thus realizing the objective of reducing the PUE value of the computer room.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic structural diagram of a cooling system provided by an embodiment of the present disclosure;

FIG. 2 is a schematic structural diagram of an evaporative cooling module 11 in the cooling system provided by an embodiment of the present disclosure;

FIG. 3 is a schematic structural diagram of a throttling module in the cooling system provided by an example of the present disclosure;

FIG. 4A is a schematic process diagram of the cooling system operating under a larger indoor load according to an embodiment of the present disclosure;

FIG. 4B is a schematic process diagram of the cooling system operating under a smaller indoor load according to an embodiment of the present disclosure;

FIG. 5 is a schematic structural diagram of a cooling system provided by an embodiment of the present disclosure;

FIG. 6 is another schematic structural diagram of a cooling system provided by an embodiment of the present disclosure; and

FIG. 7 is a flowchart of a control method for a cooling system provided by an embodiment of the present disclosure.

### DETAILED DESCRIPTION

Detailed description of implementations of the present disclosure will further be made below with reference to drawings to make the above objectives, technical solutions and advantages of the present disclosure more apparent.

At present, a server device in a data center may emit a lot of heat during operation. If the heat generated is not dissipated in time, the device in the data center will go wrong due to high temperature, which has a negative effect on normal operation of the data center. To ensure that an electronic device such as a server is kept within a stable temperature range, it is required to equip the data center with a cooling system to reduce a temperature of the electronic device such as the server in the data center. To ensure that the temperature of the computer room is kept within a reasonable range, the traditional computer room adopts mechanical refrigeration. For example, a common mechanical refrigeration cooling system available in the market is an indirect evaporative cooling system. However, mechanical refrigeration consumes as much as 35% or even exceeds 35% of total energy consumption of the data center, but refrigeration effects are poor. This brings difficulties to daily management of the computer room. In addition, use of the mechanical refrigeration will consume a lot of cooling water in the process of temperature adjustment of the computer room, which seriously wastes water resources.

On this basis, an embodiment of the present disclosure provides a cooling system, a control method and a data center computer room. A temperature of the computer room is adjusted by utilizing an oilless centrifugal compressor to reduce energy consumption of air conditioners in the computer room, thereby realizing the objective of reducing a Power Usage Effectiveness (PUE) value of the computer room.

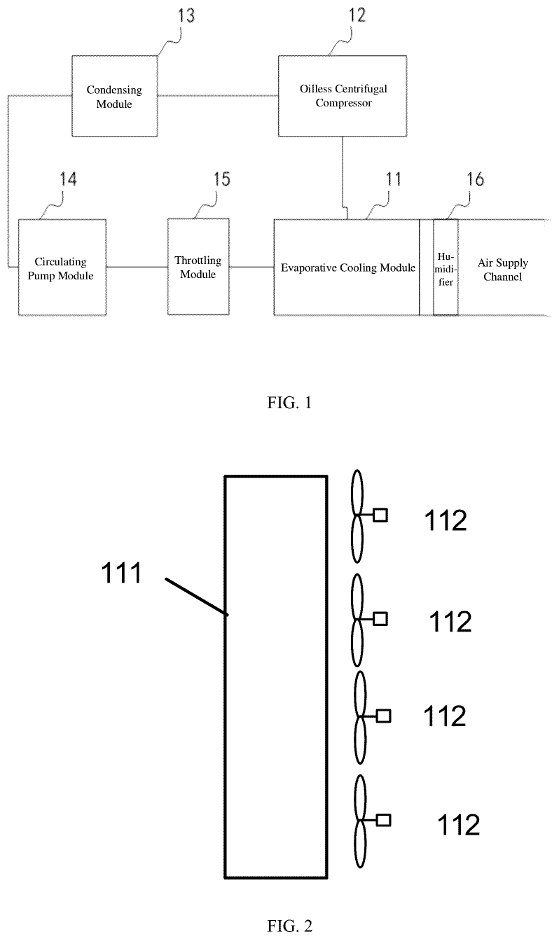

FIG. 1 is a schematic structural diagram of a cooling system provided by an embodiment of the present disclosure. Referring to FIG. 1, the cooling system provided by an embodiment of the present disclosure includes an evaporative cooling module 11, an oilless centrifugal compressor 12, a condensing module 13, a circulating pump module 14, and a throttling module 15. A first output end of the evaporative cooling module 11 is connected to an input end of the oilless centrifugal compressor 12. An output end of the oilless centrifugal compressor 12 is connected to an input end of the condensing module 13. An output end of the condensing module 13 is connected to an input end of the circulating pump module 14, and an output end of the circulating pump module 14 is connected to an input end of the throttling module 15. An output end of the throttling module 15 is connected to an input end of the evaporative cooling module 11, and a second output end of the evaporative cooling module 11 leads to an air supply channel of the data center computer room.

Referring to FIG. 1, when an outdoor temperature is higher than or equal to a preset temperature required for the data center computer room, the evaporative cooling module 11 exchanges heat with indoor hot air and a throttled refrigerant to obtain cold air and refrigerant gas, transfers the refrigerant gas to the oilless centrifugal compressor 12 through the first output end, and transfers the cold air to the data center computer room through the air supply channel by means of the second output end to cool the electronic device. The oilless centrifugal compressor 12 is configured to compress the refrigerant gas to obtain a compressed gas refrigerant. The condensing module 13 is configured to condense the compressed gas refrigerant into a liquid refrigerant. The circulating pump module 14 is configured to adjust a pressure of the liquid refrigerant; and the throttling module 15 is configured to throttle the pressure-adjusted liquid refrigerant to obtain the throttled refrigerant.

The cooling system provided by the embodiment of the present disclosure is suitable for a computer room or area where the outdoor temperature is higher than or equal to the preset temperature, and the oilless centrifugal compressor is employed to implement mechanical refrigeration. For example, when the preset temperature is 20° C. and a minimum temperature in Area A for most of a year is 25° C., the cooling system provided by the embodiment of the present disclosure may be used in the computer room positioned in the Area A. For another example, when a minimum summer temperature in Area B is 22° C. and the preset temperature is 20° C., in summer the computer room positioned in the Area B may use the cooling system provided by the embodiment of the present disclosure for temperature adjustment. The embodiments of the present disclosure are not limited to a specific value of the preset temperature.

In the process of temperature adjustment, the evaporative cooling module 11 guides the indoor hot air to the evaporative cooling module 11 by means of an indoor fan, and the throttled refrigerant generated by the throttling module 15 enters the evaporative cooling module 11. The throttled refrigerant generally is liquid, and the throttled refrigerant evaporates within the evaporative cooling module 11 and exchanges heat with the indoor hot air. The throttled refrigerant absorbs heat of the indoor hot air and evaporates into a gas refrigerant, and the indoor hot air is changed into cold air. Next, the cold air is transferred from the second output end of the evaporative cooling module 11, and reaches the electronic device such as the server in the data center computer room through the air supply channel, to cool the electronic device. A caliber of the second output end is as large as that of the air supply channel, to ensure that a large amount of cold air can be transferred to the computer room in time.

The gas refrigerant generated by the evaporative cooling module 11 enters the oilless centrifugal compressor 12 through the first output end, and the oilless centrifugal compressor 12 compresses the refrigerant gas to obtain the compressed gas refrigerant. The oilless centrifugal compressor 12 has better refrigeration performance and a higher coefficient of performance than a conventional oil compressor. Especially under a partial load of the computer room, the energy consumption is lower and the refrigeration effect is better, which is advantageous to reducing the PUE value of the computer room.

The oilless centrifugal compressor used in this embodiment is, for example, a magnetic suspension oilless centrifugal compressor or an air suspension oilless centrifugal compressor. When the magnetic suspension oilless centrifugal compressor is used, its bearing adopts a magnetic suspension bearing, which makes a rotor suspend by means of a magnetic field, such that there is no mechanical contact or mechanical friction when rotating, and so loss of transmission energy is avoided. Moreover, mechanical bearings and lubrication systems necessary for the mechanical bearings are no longer needed. When the air suspension oilless centrifugal compressor is used, its bearing may also be an air suspension bearing. The air suspension bearing uses an air film formed by gas pressurization to support the rotor to achieve support and lubrication, which has lower friction loss, better high temperature resistance, simpler structure and higher rotation accuracy.

The compressed gas refrigerant enters, through the output end of the oilless centrifugal compressor 12, into the condensing module 13, which is, for example, a condenser array or the like. The condensing module 13 cools the compressed gas refrigerant by using an outdoor natural environment cold source to obtain a liquid refrigerant. The liquid refrigerant is piped into the circulating pump module 14.

The circulating pump module 14 is configured to adjust a pressure of the liquid refrigerant. Next, the pressure-adjusted liquid refrigerant enters the throttling module 15. The throttling module 15 reduces the pressure of the pressure-adjusted liquid refrigerant from a condensation pressure to an evaporation pressure to obtain a throttled refrigerant, which facilitates evaporation and heat absorption within the evaporative cooling module 11.

As can be seen from above, the evaporative cooling module 11, the oilless centrifugal compressor 12, the condensing module 13, the circulating pump module 14 and the throttling module 15 form one complete refrigeration cycle, thus continuously adjusting the temperature of the computer room.

The cooling system provided by the embodiment of the present disclosure includes an evaporative cooling module, an oilless centrifugal compressor, a condensing module, a circulating pump module, and a throttling module. A first output end of the evaporative cooling module is connected to an input end of the oilless centrifugal compressor, an output end of the oilless centrifugal compressor is connected to an input end of the condensing module; an output end of the condensing module is connected to an input end of the circulating pump module, an output end of the circulating pump module is connected to an input end of the throttling module; and an output end of the throttling module is connected to an input end of the evaporative cooling module, and a second output end of the evaporative cooling module leads to an air supply channel. In the process of adjusting the temperature of the computer room, the cooling system exchanges heat with the indoor hot air and the throttled refrigerant by means of the evaporative cooling module to obtain the cold air and the refrigerant gas, transfers the refrigerant gas to the oilless centrifugal compressor through the first output end, and transfers the cold air to the data center computer room through the air supply channel by means of the second output end to cool the electronic device. The refrigerant gas is compressed by means of oilless centrifugal compressor to obtain the compressed gas refrigerant, which is condensed into the liquid refrigerant by the condensing module. The pressure of the liquid refrigerant is adjusted by the circulating pump module, and then the pressure-adjusted liquid refrigerant is throttled by the throttling module to obtain the throttled refrigerant, which enters the evaporative cooling module. By adopting this solution, the temperature of the computer room is adjusted by using the oilless centrifugal compressor, and energy consumption of air conditioners in the computer room is reduced, thus realizing the objective of reducing the PUE value of the computer room.

Alternatively, referring again to FIG. 1, the cooling system provided by the embodiment of the present disclosure also includes a humidifier 16, which is arranged in the air supply channel and is configured to carry out temperature and humidity treatment on the cold air to obtain the cold air conforming to a target temperature and a target humidity.

For example, the humidifier 16 may be a wet-film humidifier or the like, but the embodiments of the present disclosure are not limited thereto. By providing the humidifier 16, before the cold air enters the computer room, the humidifier carries out temperature and humidity treatment on the cold air, such that the cold air reaches the target temperature and the target humidity required for the computer room. Next, the cold air meeting the target temperature and the target humidity is transferred into the computer room.

When the wet-film humidifier is used, water in a water tank is transported to a water sprayer at a top of the humidifier, and the water is evenly sprayed to a top of a wet film. The water sprayer ensures that the water is evenly distributed to a wet-film material, and the water soaks down along the wet-film material under an action of gravity, wetting all layers inside the wet film, and being absorbed by the wet-film material to form the uniform water film. When dry cold air passes through the wet-film material, there is a larger area of contact between the dry air and a surface of the wet film, and the water fully absorbs heat of the air and vaporizes and evaporates, thus achieving a purpose of humidifying the air. In this humidification process, the humidity of the air increases and the temperature drops.

By adopting this solution, the humidifier is arranged and so no additional dehumidification unit is needed, thus the requirements of the computer room for humidity and temperature of the cold air can be met with lower costs.

FIG. 2 is a schematic structural diagram of an evaporative cooling module 11 in the cooling system provided by an embodiment of the present disclosure. Referring to FIG. 2, the evaporative cooling module 11 includes an evaporator 111 and a plurality of indoor fans 112. The plurality of indoor fans 112 are uniformly arranged on a side of the evaporator 111 near the air supply channel, and the plurality of indoor fans 112 are configured to guide the indoor hot air to the evaporator 111. The evaporator 111 is configured to exchange heat with the indoor hot air and the throttled refrigerant to obtain the cold air and the gas refrigerant.

The evaporator 111 may be an indoor fin heat exchanger or the like, but the embodiments of the present disclosure are not limited thereto. One evaporator 111 corresponds to a plurality of indoor fans 112. After the throttled refrigerant is transferred to the evaporator 111, when the indoor hot air passes through the evaporator 111, the throttled refrigerant absorbs heat and is converted into gas refrigerant, which enters the condensing module 12. The indoor circulating cold air enters the computer room through the air supply channel to cool the electronic device such as the server.

By adopting this solution, a one-to-many relationship is between the evaporator and the indoor fans, which provides a simpler structure, lower costs, and more uniform air supply temperature.

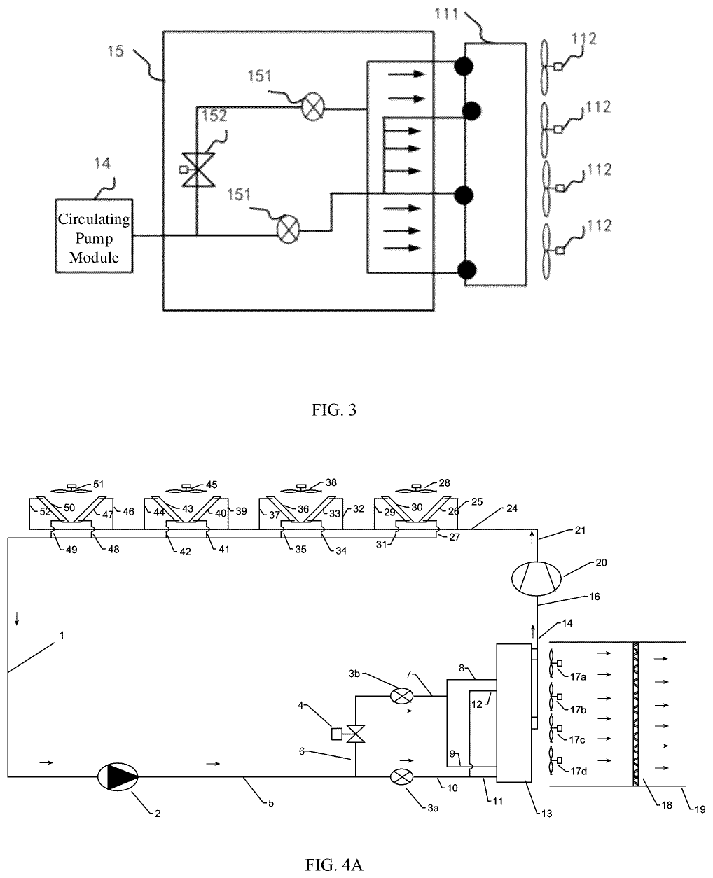

FIG. 3 is a schematic structural diagram of a throttling module in the cooling system provided by an example of the present disclosure. Referring to FIG. 2, the throttling module 15 provided by an embodiment of the present disclosure includes at least one electronic expansion valve 151. An input end of each electronic expansion valve 151 is connected to the output end of the circulating pump module. Each electronic expansion valve 151 has at least two output ends, and each of the at least two output ends is connected to the evaporative cooling module 11 to transfer the throttled refrigerant to the evaporative cooling module 11.

For example, the evaporator 111 of the evaporative cooling module 11 has a distributor therein, which is internally provided with a plurality of input ends for entry of the throttled refrigerant. Number of the input ends corresponds to the output end of the throttling module 15 one to one. After the throttling module 15 receives the pressure-adjusted liquid refrigerant from the circulating pump module 14, the liquid refrigerant is divided into multiple paths and flows to the electronic expansion valve 151, and the electronic expansion valve 151 throttles the liquid refrigerant to obtain the throttled and depressurized refrigerant. Each electronic expansion valve 151 has one or more output ends, each of which is connected to an input end on the distributor of the evaporative cooling module 11 (black filling circles in the figure represent intersection points between the input ends and pipes between side walls of the evaporator 11), such that the throttled refrigerant is transferred to the distributor.

It should be noted that only two electronic expansion valves 151 are illustrated in FIG. 3. However, more or fewer electronic expansion valves may be provided in practice. Moreover, in addition to the electronic expansion valve 151, the throttling module 15 may also include a solenoid valve 152 and the like, but the embodiments of the present disclosure are not limited thereto.

Furthermore, it should be noted that throttling is achieved by means of the electronic expansion valve 151 in FIG. 3, but the embodiments of the present disclosure are not limited thereto. In other feasible implementations, the throttling module 151 may also be implemented by means of a capillary tube or a thermal expansion valve.

By adopting this solution, the pressure-adjusted liquid refrigerant is throttled and depressurized by means of the electronic expansion valve in the throttling module, such that a flow rate of the refrigerant can be accurately controlled, and thus an evaporation temperature can be accurately controlled.

Alternatively, in the above embodiment, a plurality of input ends are provided on the evaporator of the evaporative cooling module 11, at least two output ends of each electronic expansion valve 151 of the throttling module 15 are respectively connected to different input ends of the evaporative cooling module, and the plurality of input ends on the evaporator of the evaporative cooling module 11 are uniformly distributed on the evaporative cooling module 11.

Referring to FIG. 3 again, in the embodiment of the present disclosure, the evaporative cooling module 11 includes an evaporator and a plurality of indoor fans. A distributor is arranged in the evaporator 11, and a plurality of input ends are arranged on side walls of the distributor. The plurality of input ends are uniformly distributed on the evaporative cooling module. That is, the plurality of input ends are uniformly distributed on the side walls of the distributor. For example, the black filling circles in the figure in FIG. 3 represent the intersection points between the input ends and the pipes between the side walls of the evaporator 11, where these intersection points are uniformly distributed on the side walls of the evaporator, and accordingly, the plurality of input ends are uniformly distributed on the side walls of the distributor.

When the plurality of input ends are uniformly distributed on the side walls of the distributor on the evaporative cooling module 11, the multipath liquid refrigerant can uniformly enter the evaporator, such that the liquid refrigerant in the distributor of the evaporator is uniformly distributed. After the indoor hot air enters, the indoor hot air is shown as arrows in the figure. Because the liquid refrigerant in the distributor is uniformly distributed, the cold air obtained after the indoor hot air flowing through different parts of the evaporator is cooled is uniform in temperature, and a phenomenon of uneven hot and cold will not occur. For example, the evaporator is divided into a lower part and an upper part in turn from bottom to top. In the event of uneven hot and cold, the cold air obtained has a higher temperature after the heat exchange between the indoor hot air flowing through the upper part and the liquid refrigerant, while the cold air obtained has a lower temperature after the heat exchange between the indoor hot air flowing through the lower part and the liquid refrigerant.

By adopting this solution, the input ends of the evaporative cooling module are uniformly arranged, such that after the indoor hot air flows through the evaporative cooling module, the cold air obtained has a uniform temperature, and thus the refrigeration effect is improved.

Alternatively, in the above embodiment, the throttling module 15 includes at least one electronic expansion valve 151, number of the electronic expansion valves 151 participating in throttling among the at least one electronic expansion valve 151 is associated with an indoor load of the computer room. When the indoor load is within a first range, the number of the electronic expansion valves 151 participating in throttling among the at least one electronic expansion valve 151 is a first number.

When the indoor load is within a second range, the number of the electronic expansion valves 151 participating in throttling among the at least one electronic expansion valve 151 is a second number, where the first range and the second range are two adjacent load ranges. A maximum load of the first range is lower than a minimum load of the second range, and the first number is less than the second number.

For example, the greater the indoor load is, i.e., the greater the computer room load is, the greater the number of the electronic expansion valves 151 participating in throttling among the at least one electronic expansion valve 151 is. The smaller the indoor load is, the smaller the number of the electronic expansion valves 151 participating in throttling among the at least one electronic expansion valve 151 is, i.e., the fewer the electronic expansion valves 151 simultaneously operating are. A plurality of load ranges are divided in advance according to an order of the loads from high to low, and different load ranges correspond to different numbers of the electronic expansion valves. The cooling system adjusts the number of the electronic expansion valves enabled in real time according to the current indoor load. For example, the indoor load is greater even if the outdoor temperature is lower. In this case, the number of the electronic expansion valves simultaneously participating in throttling is also greater.

By adopting this solution, the number of the electronic expansion valves simultaneously participating in throttling is adjusted according to the indoor load, to achieve the objective of accurately adjusting the temperature of the computer room.

Several examples are provided below to describe the above cooling system in detail.

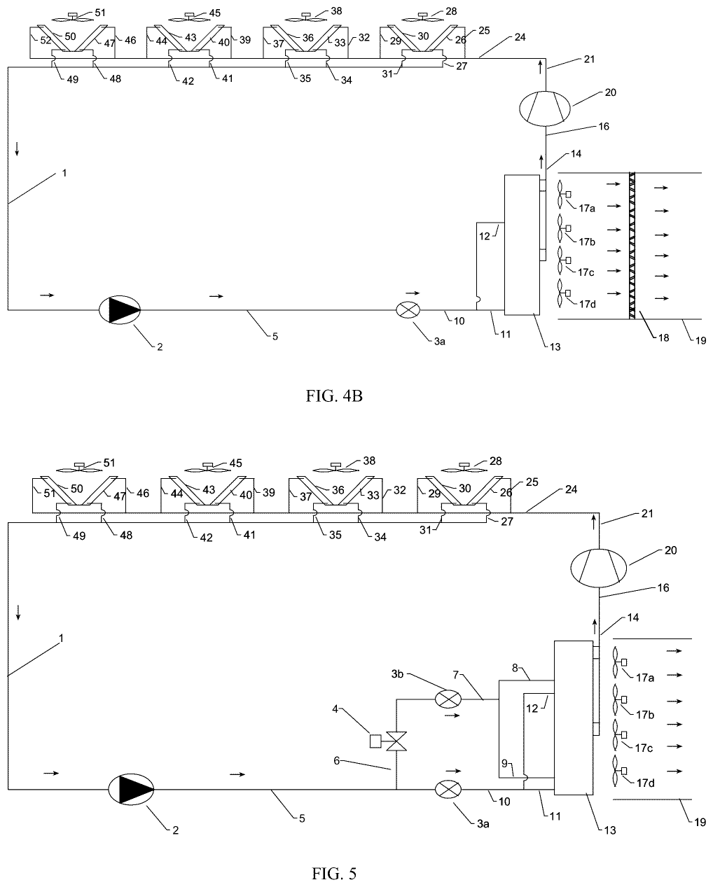

FIG. 4A is a schematic process diagram of the cooling system operating under a larger indoor load according to an embodiment of the present disclosure. Referring to FIG. 4A, the evaporative cooling module of the cooling system includes an evaporator 13, and indoor fans 17a, 17b, 17c, and 17d. The oilless centrifugal compressor is, for example, the oilless centrifugal compressor 20 in the figure. The condensing module includes outdoor fans 28, 38, 45 and 51, and condensers 26/30, 33/36, 40/43 and 47/50. The condensing module also includes an exhaust manifold 24 and a liquid outlet manifold 1. The liquid outlet manifold 1 is provided with liquid outlet pipelines 27/31, 34/35, 41/42 and 48/49; and the exhaust manifold 24 is provided with air inlet pipelines 25/29, 32/37, 39/44, and 46/52. The circulating pump module is, for example, a circulating pump 2; and the throttling module includes an electronic expansion valve 3a, an electronic expansion valve 3, and a solenoid valve 4.

In addition, the cooling system also includes connecting pipes and other components, such as distribution pipelines 7, 8, 9, 10, 11 and 12 for the throttled refrigerant, a liquid outlet pipe 5, a connecting pipe 6, an air return pipeline 14, a circulating pump 2, a humidifier 18, a suction pipeline 16 and an exhaust pipeline 21 of the oilless centrifugal compressor 20, etc. In practice, the cooling system may include more or fewer components, but the embodiments of the present disclosure are not limited thereto.

Referring to FIG. 4A, the condensing module operates when the outdoor temperature is higher than or equal to the preset temperature required for the data center computer room. The condensing module includes four outdoor heat exchanger assemblies, each of which includes an outdoor fan and at least two condensers. In the figure, the outdoor fans are represented by numerals 28, 38, 45 and 51, and the condensers are represented by numerals 26/30, 33/36, 40/43, and 47/50. The outdoor fan 28 corresponds to the condenser 26/30, the outdoor fan 38 corresponds to the condenser 33/36, the outdoor fan 45 corresponds to the condenser 40/43 and the outdoor fan 51 corresponds to the condenser 47/50.

In the process of temperature adjustment, guided by an indoor air duct and driven by the indoor fans 17a, 17b, 17c and 17d, the indoor hot air from the data computer room enters the evaporator 13. The cold air and the gas refrigerant are obtained by means of heat exchange, which is carried out in the evaporator 13, between the indoor hot air and the throttled refrigerant. The cold air flows out from an indoor heat exchange channel (i.e., the second output end) of the evaporator 13, and then is subjected to temperature and humidity treatment by the humidifier 18. The treated cold air is transferred to the data center computer room through the air supply channel 19 to cool the electronic device such as a server.

The refrigerant gas flows through the suction pipeline 16 of the oilless centrifugal compressor 20 by means of the air return pipeline 14, and enters the oilless centrifugal compressor 20. The oilless centrifugal compressor 20 compresses the gas refrigerant to obtain the compressed gas refrigerant. The compressed gas refrigerant enters the exhaust manifold 24 through the exhaust pipeline 21 of the oilless centrifugal compressor 20. Next, the gas refrigerant in the exhaust manifold 24 flows through the air inlet pipelines 25/29, 32/37, 39/44 and 46/52, and enters the condensers 26/30, 33/36, 40/43, and 47/50, respectively. The outdoor fans 28, 38, 45 and 51 guide outdoor natural cold sources to around the condensers 26/30, 33/36 and 40/43, thereby cooling the gas refrigerant to obtain a liquid refrigerant, and discharging heat released by the gas refrigerant into outdoor atmosphere.

The liquid refrigerant enters the liquid outlet manifold 1 through the liquid outlet pipelines 27/31, 34/35, 41/42 and 48/49, and after being adjusted and pressurized by the circulating pump 2, the liquid refrigerant is divided into two paths and enters the throttling module for throttling. One path of the liquid refrigerant flows through the solenoid valve 4 and the electronic expansion valve 3b in turn, and the other path of the liquid refrigerant flows through the electronic expansion valve 3a. After reaching the electronic expansion valve 3a for throttling, the liquid refrigerant enters the evaporator 13 through the distribution pipelines 7, 8 and 9. After reaching the electronic expansion valve 3b, the liquid refrigerant enters the evaporator 13 through the distribution pipelines 10, 11, and 12. The throttled refrigerant entering the evaporator 13 continues to exchange heat with the indoor hot air, thus forming one complete refrigeration cycle.

FIG. 4B is a schematic process diagram of the cooling system operating under a smaller indoor load according to an embodiment of the present disclosure. In contrast to FIG. 4A, when the indoor load is smaller, only one electronic expansion valve 3a is in operation.

In the process of temperature adjustment, the refrigerant gas flows through the suction pipeline 16 of the oilless centrifugal compressor 20 by means of the air return pipeline 14, and enters the oilless centrifugal compressor 20. The oilless centrifugal compressor 20 compresses the gas refrigerant to obtain the compressed gas refrigerant. The compressed gas refrigerant enters the exhaust manifold 24 through the exhaust pipeline 21 of the oilless centrifugal compressor 20. Next, the gas refrigerant in the exhaust manifold 24 flows through the air inlet pipelines 25/29, 32/37, 39/44 and 46/52, and enters the condensers 26/30, 33/36, 40/43, and 47/50, respectively. The outdoor fans 28, 38, 45 and 51 guide outdoor natural cold sources to around the condensers 26/30, 33/36 and 40/43, thereby cooling the gas refrigerant to obtain a liquid refrigerant, and discharging heat released by the gas refrigerant into outdoor atmosphere.

The liquid refrigerant enters the liquid outlet manifold 1 through the liquid outlet pipelines 27/31, 34/35, 41/42 and 48/49, and after being adjusted and pressurized by the circulating pump 2, the liquid refrigerant is throttled by means of the electronic expansion valve 3a of the throttling module. After reaching the electronic expansion valve 3a for throttling, the liquid refrigerant enters the evaporator 13 through the distribution pipelines 7, 8, and 9. The throttled refrigerant entering the evaporator 13 continues to exchange heat with the indoor hot air, thus forming one complete refrigeration cycle.

In the above-mentioned FIGS. 4A and 4B, a description is made by taking an example where the cooling system includes the humidifier. However, the embodiments of the present disclosure are not limited thereto. In other feasible implementations, the cooling system may not include the humidifier. For example, reference is made to FIG. 5.

FIG. 5 is a schematic structural diagram of a cooling system provided by an embodiment of the present disclosure. Referring to FIG. 5, compared with FIGS. 4A and 4B, in this embodiment, the air supply channel is not provided with the humidifier.

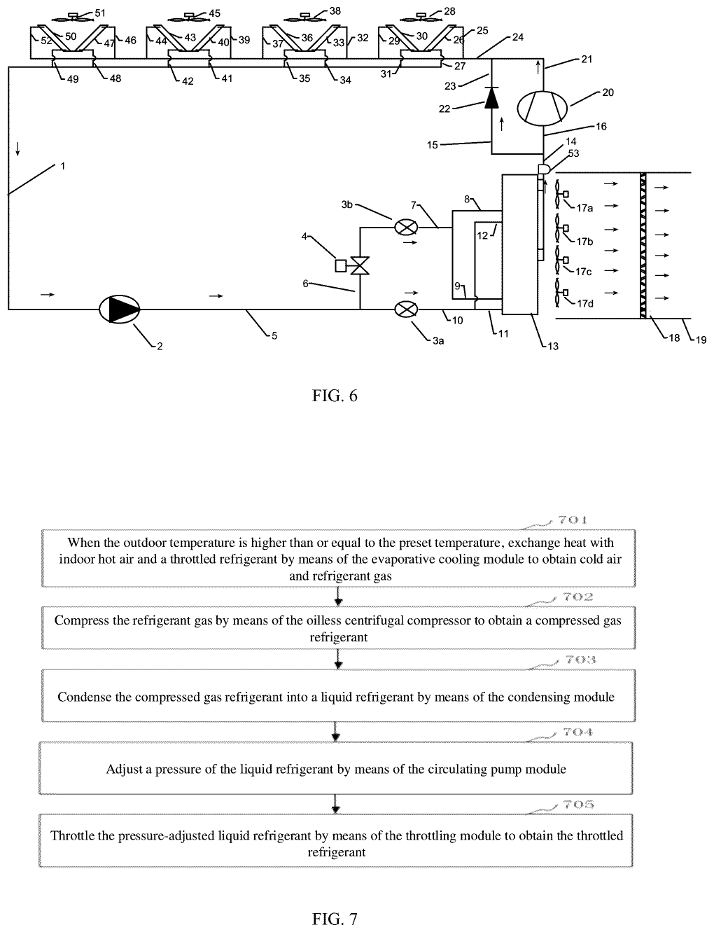

FIG. 6 is another schematic structural diagram of a cooling system provided by an embodiment of the present disclosure. Referring to FIG. 6, in this embodiment, the cooling system also includes a one-way valve 22, which has a one-way valve air inlet pipeline 15 and a one-way valve air outlet pipeline 23. The one-way valve air inlet pipeline 15 (input end) is communicated with the air return pipeline 14 (i.e. the first output end of the heat exchange module) of the evaporator 13, and the one-way valve air outlet pipeline 23 (output end) is connected to the input end of the exhaust manifold 24, where the input end of the exhaust manifold 24 is the input end of the condensing module.

The oilless centrifugal compressor 20 has a suction pipeline 16 (input end) and an exhaust pipeline 21 (output end). The suction pipeline 16 is communicated with the air return pipeline 14 (i.e., the first output end of the heat exchange module) of the evaporator 13, and the exhaust pipeline 21 is communicated with the exhaust manifold 24.

When the outdoor temperature is greater than or equal to the preset temperature, the oilless centrifugal compressor 20 operates to guide the gas refrigerant to the condensing module. That is, after the gas refrigerant is compressed by the oilless centrifugal compressor, the compressed gas refrigerant enters each condenser through the exhaust pipeline 21 in FIG. 6. When the oilless centrifugal compressor 20 is operating, the one-way valve 22 is closed to prevent the gas refrigerant from entering the condensing module through the one-way valve 22. That is, when the outdoor temperature is higher than the preset temperature, the refrigerant gas passes through the oilless centrifugal compressor 20 and then enters the condensing module for cooling, which adopts a mechanical refrigeration mode.

When the outdoor temperature is lower than the preset temperature, the oilless centrifugal compressor 20 does not operate, and the one-way valve 22 is enabled. In this case, it is not required to compress the gas refrigerant, instead the gas refrigerant is directly guided to the condensing module, and a natural cold source is used for cooling.

By adopting this solution, it is determined whether to use the mechanical refrigeration or natural cold source refrigeration by comparing the outdoor temperature with the preset temperature, to accurately adjust the temperature of the computer room and save energy consumption, thus achieving the objective of reducing the PUE value of the computer room.

Alternatively, referring to FIG. 6 again, the cooling system provided by the embodiment of the present disclosure further includes a temperature sensor 53, which is connected to the one-way valve 22 and the oilless centrifugal compressor 20. The temperature sensor 53 is configured to detect the outdoor temperature and to control the one-way valve 20 and the oilless centrifugal compressor 22 according to the outdoor temperature.

For example, the temperature sensor 53 is a component capable of collecting the outdoor temperature. After the outdoor temperature is collected, the outdoor temperature is fed back to a processor (schematically shown in the figure), and the processor compares the outdoor temperature with the preset temperature to determine whether the mechanical refrigeration or the natural cold source refrigeration is adopted.

By adopting this solution, the temperature sensor is arranged to flexibly switch the refrigeration mode in time, making the structure simpler and costs lower.

Based on the above-mentioned cooling system, an embodiment of the present disclosure also provides a data center computer room, which is internally provided with the above-mentioned cooling system.

An embodiment of the present disclosure also provides a control method for a cooling system, which is applied to the above-mentioned cooling system. FIG. 7 is a flowchart of the control method for the cooling system provided by the embodiment of the present disclosure. The control method includes following steps:

Step 701, when the outdoor temperature is higher than or equal to the preset temperature, exchanging heat with indoor hot air and a throttled refrigerant by means of the evaporative cooling module to obtain cold air and refrigerant gas;

Step 702, compressing the refrigerant gas by means of the oilless centrifugal compressor to obtain a compressed gas refrigerant;

Step 703, condensing the compressed gas refrigerant into a liquid refrigerant by means of the condensing module;

Step 704, adjusting a pressure of the liquid refrigerant by means of the circulating pump module; and

Step 705, throttling the pressure-adjusted liquid refrigerant by means of the throttling module to obtain the throttled refrigerant.

Reference may be made to the above description of the cooling system for a specific implementation process, which will not be repeated here.

Alternatively, the throttling module includes at least one electronic expansion valve, and the cooling system uses the throttling module to throttle the pressure-adjusted liquid refrigerant to determine the indoor load of the computer room when the throttled refrigerant is obtained. Next, the cooling system determines the number of the electronic expansion valves participating in throttling among the at least one electronic expansion valve according to the indoor load, enables the electronic expansion valves corresponding to the number, and then throttles the liquid refrigerant by means of the enabled electronic expansion valves to obtain the throttled refrigerant.

Reference may be made in detail to the above description of FIGS. 4A and 4B, and thus detailed descriptions thereof are omitted here.

An embodiment of the present disclosure also provides a computer-readable storage medium storing computer instructions which, when executed by a processor, are configured for implementing the control method for the cooling system.

An embodiment of the present disclosure also provides a computer program product comprising a computer program that, when executed by the processor, implements the control method for the cooling system.

Other embodiments of the present disclosure will be apparent to those skilled in the art from consideration of the specification and practice of the invention disclosed here. The present disclosure is intended to cover any variations, uses, or adaptations of the present disclosure following the general principles thereof and including such departures from the present disclosure as come within known or customary practice in the art. It is intended that the specification and embodiments be considered as exemplary only, with a true scope and spirit of the present disclosure being indicated by the following claims.

It will be appreciated that the present disclosure is not limited to the exact construction that has been described above and illustrated in the accompanying drawings, and that various modifications and changes can be made without departing from the scope thereof. It is intended that the scope of the present disclosure only be limited by the appended claims.

What is claimed is:

1. A cooling system, comprising an evaporative cooling module, an oilless centrifugal compressor, a condensing module, a circulating pump module and a throttling module, a first output end of the evaporative cooling module being connected to an input end of the oilless centrifugal compressor, an output end of the oilless centrifugal compressor being connected to an input end of the condensing module, an output end of the condensing module being connected to an input end of the circulating pump module, an output end of the circulating pump module being connected to an input end of the throttling module, an output end of the throttling module being connected to an input end of the evaporative cooling module, and a second output end of the evaporative cooling module leading to an air supply channel of a data center computer room, wherein:
the evaporative cooling module is configured to, when an outdoor temperature is higher than or equal to a preset temperature, exchange heat with indoor hot air and a throttled refrigerant to obtain cold air and refrigerant gas, transfer the refrigerant gas to the oilless centrifugal compressor through the first output end, and transfer the cold air to an electronic device through the air supply channel by means of the second output end;
the oilless centrifugal compressor is configured to compress the refrigerant gas to obtain a compressed gas refrigerant;
the condensing module is configured to condense the compressed gas refrigerant into a liquid refrigerant;
the circulating pump module is configured to adjust a pressure of the liquid refrigerant; and
the throttling module is configured to throttle the pressure-adjusted liquid refrigerant to obtain the throttled refrigerant.

2. The cooling system according to claim 1, wherein the throttling module comprises at least one electronic expansion valve, an input end of each electronic expansion valve is connected to the output end of the circulating pump module, each electronic expansion valve has at least two output ends, and each of the at least two output ends is connected to the evaporative cooling module to transfer the throttled refrigerant to the evaporative cooling module.

3. The cooling system according to claim 2, wherein
the evaporative cooling module is provided with a plurality of input ends, the at least two output ends are respectively connected to different input ends of the evaporative cooling module, and the plurality of input ends are uniformly distributed on the evaporative cooling module.

4. The cooling system according to claim 2, wherein
number of the electronic expansion valves participating in throttling among the at least one electronic expansion valve is associated with an indoor load of the computer room; when the indoor load is within a first range, the number of the electronic expansion valves participating in throttling among the at least one electronic expansion valve is a first number; and
when the indoor load is within a second range, the number of the electronic expansion valves participating in throttling among the at least one electronic expansion valve is a second number, the first range and the second range are two adjacent load ranges, a maximum load of the first range is lower than a minimum load of the second range, and the first number is less than the second number.

5. The cooling system according to claim 4, wherein
the evaporative cooling module comprises an evaporator and a plurality of indoor fans, and the plurality of indoor fans are uniformly distributed on one side of the evaporator facing toward the air supply channel.

6. The cooling system according to claim 4, further comprising:
a humidifier arranged in the air supply channel, the humidifier being configured to treat a temperature and a humidity of the cold air to obtain cold air conforming to a target temperature and a target humidity.

7. The cooling system according to claim 4, further comprising:
a one-way valve, an input end of the one-way valve being connected to the first output end of the evaporative cooling module, an output end of the one-way valve being connected to an input end of an exhaust manifold, and an output end of the exhaust manifold being connected to the input end of the condensing module;
when the outdoor temperature is higher than or equal to the preset temperature, the oilless centrifugal compressor operates to guide the gas refrigerant to the condensing module, and the one-way valve is closed to stop the gas refrigerant from entering the condensing module through the one-way valve; and
when the outdoor temperature is lower than the preset temperature, the oilless centrifugal compressor does not operate, and the one-way valve is opened to guide the gas refrigerant to the condensing module.

8. The cooling system according to claim 7, further comprising:
a temperature sensor, the temperature sensor being connected to the one-way valve and the oilless centrifugal compressor, and being configured to detect the outdoor temperature and control the one-way valve and the oilless centrifugal compressor according to the outdoor temperature.

9. A data center computer room, comprising: a computer room internally provided with a cooling system, wherein the cooling system, comprising an evaporative cooling module, an oilless centrifugal compressor, a condensing module, a circulating pump module and a throttling module, a first output end of the evaporative cooling module being connected to an input end of the oilless centrifugal compressor, an output end of the oilless centrifugal compressor being connected to an input end of the condensing module, an output end of the condensing module being connected to an input end of the circulating pump module, an output end of the circulating pump module being connected to an input end of the throttling module, an output end of the throttling module being connected to an input end of the evaporative cooling module, and a second output end of the evaporative cooling module leading to an air supply channel of a data center computer room, wherein:
the evaporative cooling module is configured to, when an outdoor temperature is higher than or equal to a preset temperature, exchange heat with indoor hot air and a throttled refrigerant to obtain cold air and refrigerant gas, transfer the refrigerant gas to the oilless centrifugal compressor through the first output end, and transfer the cold air to an electronic device through the air supply channel by means of the second output end;
the oilless centrifugal compressor is configured to compress the refrigerant gas to obtain a compressed gas refrigerant;
the condensing module is configured to condense the compressed gas refrigerant into a liquid refrigerant;
the circulating pump module is configured to adjust a pressure of the liquid refrigerant; and
the throttling module is configured to throttle the pressure-adjusted liquid refrigerant to obtain the throttled refrigerant.

10. The data center computer room according to claim 9, wherein the throttling module comprises at least one electronic expansion valve, an input end of each electronic expansion valve is connected to the output end of the circulating pump module, each electronic expansion valve has at least two output ends, and each of the at least two output ends is connected to the evaporative cooling module to transfer the throttled refrigerant to the evaporative cooling module.

11. The data center computer room according to claim 10, wherein
the evaporative cooling module is provided with a plurality of input ends, the at least two output ends are respectively connected to different input ends of the evaporative cooling module, and the plurality of input ends are uniformly distributed on the evaporative cooling module.

12. The data center computer room according to claim 10, wherein
number of the electronic expansion valves participating in throttling among the at least one electronic expansion valve is associated with an indoor load of the computer room; when the indoor load is within a first range, the number of the electronic expansion valves participating in throttling among the at least one electronic expansion valve is a first number; and
when the indoor load is within a second range, the number of the electronic expansion valves participating in throttling among the at least one electronic expansion valve is a second number, the first range and the second range are two adjacent load ranges, a maximum load of the first range is lower than a minimum load of the second range, and the first number is less than the second number.

13. The data center computer room according to claim 12, wherein
the evaporative cooling module comprises an evaporator and a plurality of indoor fans, and the plurality of indoor fans are uniformly distributed on one side of the evaporator facing toward the air supply channel.

14. The data center computer room according to claim 12, further comprising:
a humidifier arranged in the air supply channel, the humidifier being configured to treat a temperature and a humidity of the cold air to obtain cold air conforming to a target temperature and a target humidity.

15. The data center computer room according to claim 12, further comprising:
a one-way valve, an input end of the one-way valve being connected to the first output end of the evaporative cooling module, an output end of the one-way valve being connected to an input end of an exhaust manifold, and an output end of the exhaust manifold being connected to the input end of the condensing module;
when the outdoor temperature is higher than or equal to the preset temperature, the oilless centrifugal compressor operates to guide the gas refrigerant to the condensing module, and the one-way valve is closed to stop the gas refrigerant from entering the condensing module through the one-way valve; and
when the outdoor temperature is lower than the preset temperature, the oilless centrifugal compressor does not operate, and the one-way valve is opened to guide the gas refrigerant to the condensing module.

16. The data center computer room according to claim 15, further comprising:
a temperature sensor, the temperature sensor being connected to the one-way valve and the oilless centrifugal compressor, and being configured to detect the outdoor temperature and control the one-way valve and the oilless centrifugal compressor according to the outdoor temperature.

17. A control method for a cooling system, the control method being applied to an evaporative cooling module, an oilless centrifugal compressor, a condensing module, a circulating pump module and a throttling module, a first output end of the evaporative cooling module being connected to an input end of the oilless centrifugal compressor, an output end of the oilless centrifugal compressor being connected to an input end of the condensing module, an output end of the condensing module being connected to an input end of the circulating pump module, an output end of the circulating pump module being connected to an input end of the throttling module, an output end of the throttling module being connected to an input end of the evaporative cooling module, and a second output end of the evaporative cooling module leading to an air supply channel, and the control method comprising:
when an outdoor temperature is higher than or equal to a preset temperature, exchanging heat with indoor hot air and a throttled refrigerant by means of the evaporative cooling module to obtain cold air and refrigerant gas;
compressing the refrigerant gas by means of the oilless centrifugal compressor to obtain a compressed gas refrigerant;
condensing the compressed gas refrigerant into a liquid refrigerant by means of the condensing module;
adjusting a pressure of the liquid refrigerant by means of the circulating pump module; and
throttling the pressure-adjusted liquid refrigerant by means of the throttling module to obtain the throttled refrigerant.
